(19) United States
(12) Patent Application Publication
(10) Pub. No.: US 2026/0177925 A1
(43) Pub. Date: Jun. 25, 2026

(54) ILLUMINATION OPTICAL SYSTEM, EXPOSURE APPARATUS INCLUDING THE SAME, AND EXPOSURE METHOD THEREOF

(71) Applicant: Samsung Display Co., LTD., Yongin-si (KR)

(72) Inventors: Akifumi SANGU, Yongin-si (KR); Cheol Ho PARK, Yongin-si (KR); Young Su CHAE, Yongin-si (KR)

(21) Appl. No.: 19/285,512

(22) Filed: Jul. 30, 2025

(30) Foreign Application Priority Data
Dec. 19, 2024 (KR) 10-2024-0191766

(51) Int. Cl. G03F 7/00; G03F 7/20

(52) U.S. Cl. CPC G03F 7/7015; G03F 7/2002

(57) ABSTRACT

An exposure apparatus includes a light source emitting light, an axicon lens converging the light emitted from the light source, and a fly-eye lens portion receiving the light converged from the axicon lens, and the axicon lens and the fly-eye lens portion are aligned next (adjacent) to each other.

This application claims priority to Korean Patent Application No. 10-2024-0191766, filed on Dec. 19, 2024, and all the benefits accruing therefrom under 35 U.S.C. § 119, the content of which in its entirety is herein incorporated by reference.

### BACKGROUND

### (a) Field

The disclosure relates to an exposure apparatus, an illumination optical system, and an exposure method.

### (b) Description of the Related Art

An exposure apparatus may be used in a photolithography process to form a pattern on a semiconductor device, a printed circuit board, and a liquid crystal substrate. The exposure apparatus may form a pattern on the substrate by exposing light onto the photosensitive material.

An exposure apparatus with improved illumination and resolution, an illumination optical system, and an exposure method may be advantageous for rapidly and precisely forming a fine pattern on a substrate.

### SUMMARY

The disclosure attempts to provide an exposure apparatus, illumination optical system, and exposure method.

Embodiments attempt to provide an exposure apparatus, an illumination optical system, and an exposure method with improved illumination and resolution.

An embodiment of the disclosure provides an exposure apparatus including a light source configured to emit light, an axicon lens configured to converge the light emitted from the light source, and a fly-eye lens portion configured to receive the light converged from the axicon lens, wherein the axicon lens and the fly-eye lens portion are aligned next (adjacent) to each other.

In an embodiment, the exposure apparatus may further include a light range adjustment lens portion disposed between the light source and the axicon lens and configured to adjust a light irradiation range of the light emitted from the light source.

In an embodiment, the exposure apparatus may further include a condenser lens portion configured to receive light emitted from the fly-eye lens portion and configured to adjust illuminance of the emitted light to be uniform.

In an embodiment, the fly-eye lens portion may include a first aperture including a transmissive region that transmits light, and the first aperture may directly receive light from the axicon lens, and the axicon lens and the first aperture are aligned next (adjacent) to each other.

In an embodiment, a first surface of the axicon lens may have a conical shape.

In an embodiment, a first surface of the axicon lens may have a truncated cone shape including a generatrix and a flat upper base.

In an embodiment, a diameter of the flat upper base disposed on the first surface of the axicon lens may be 40 millimeters (mm) to 60 mm.

In an embodiment, a second surface of the axicon lens, which is opposite to the first surface, may face the fly-eye lens portion.

In an embodiment, a groove having a truncated cone shape may be defined in a second surface of the axicon lens which is opposite to the first surface.

An embodiment of the disclosure provides an illumination optical system including an axicon lens configured to converge light emitted from a light source, and a fly-eye lens portion configured to receive the light converged from the axicon lens, wherein the axicon lens and the fly-eye lens portion are aligned next (adjacent) to each other.

In an embodiment, the illumination optical system may further include a condenser lens portion configured to receive light emitted from the fly-eye lens portion and configured to adjust illuminance of the emitted light to be uniform.

In an embodiment, the fly-eye lens portion may include a first aperture including a transmissive region that transmits light, and the first aperture may directly receive light from the axicon lens, and the axicon lens and the first aperture are aligned next (adjacent) to each other.

In an embodiment, a first surface of the axicon lens may have a conical shape.

In an embodiment, a first surface of the axicon lens may have a truncated cone shape including a generatrix and a flat upper base.

In an embodiment, a diameter of the flat upper base disposed on the first surface of the axicon lens may be 40 mm to 60 mm.

In an embodiment, a second surface of the axicon lens, which is opposite to the first surface, may face the fly-eye lens portion.

In an embodiment, a groove having a truncated cone shape may be defined in a second surface of the axicon lens which is opposite to the first surface.

An embodiment of the disclosure provides an exposure method including preparing an exposure apparatus including a light source, an axicon lens, and a fly-eye lens portion, emitting light from the light source, converging the light emitted from the light source by the axicon lens, and transferring the light converged from the axicon lens to the fly-eye lens portion aligned next (adjacent) to the axicon lens.

In an embodiment, the fly-eye lens portion may include a first aperture that includes a transmissive region and is aligned next (adjacent) to the axicon lens, and the transferring of the light converged from the axicon lens to the fly-eye lens portion aligned next (adjacent) to the axicon lens may include the first aperture of the fly-eye lens portion directly receiving the light.

In an embodiment, a first surface of the axicon lens may have a truncated cone shape including a generatrix and an upper base, and a second surface of the axicon lens, which is opposite to the first surface, may face the fly-eye lens portion.

By the embodiments, the illuminance and resolution of the exposure apparatus and the illumination optical system may be improved by aligning the fly-eye lens portion and the axicon lens next (adjacent) to each other.

In addition, the illumination and resolution of the exposure method may be improved by transmitting the light converged from the axicon lens to the fly-eye lens portion aligned next (adjacent) to the axicon lens.

Further, in the embodiments, there are other advantageous effects that may be recognized throughout the specification.

### BRIEF DESCRIPTION OF THE DRAWINGS

The above and other embodiments, advantages and features of this disclosure will become more apparent by describing in further detail embodiments thereof with reference to the accompanying drawings, in which:

FIG. 1 illustrates a schematic diagram showing an embodiment of an exposure apparatus.

FIG. 2 illustrates an embodiment of an illumination optical system.

FIG. 3 illustrates a perspective view showing a first fly-eye lens and a second fly-eye lens.

FIG. 4 illustrates light transferred from an axicon lens to a fly-eye lens portion.

FIG. 5 illustrates a perspective view showing an embodiment of an axicon lens.

FIG. 6A illustrates a side view showing an embodiment of an axicon lens, and FIG. 6B is an enlarged view of a dot-dashed portion of FIG. 6B.

FIG. 7 illustrates a perspective view showing another embodiment of an axicon lens.

FIG. 8 illustrates a cross-sectional view showing another embodiment of an axicon lens.

FIG. 9 illustrates a perspective view showing another embodiment of an axicon lens.

FIG. 10 illustrates a cross-sectional view showing another embodiment of an axicon lens.

FIG. 11 illustrates a perspective view showing another embodiment of an axicon lens.

FIG. 12 illustrates a cross-sectional view showing another embodiment of an axicon lens.

FIG. 13 illustrates a flowchart of an embodiment of an exposure method according to the disclosure.

### DETAILED DESCRIPTION

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

To clearly describe the disclosure, parts that are irrelevant to the description are omitted, and like numerals refer to like or similar components throughout the specification.

Further, since sizes and thicknesses of constituent members shown in the accompanying drawings are arbitrarily given for better understanding and ease of description, the disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It should be understood that when an element such as a layer, film, region, or substrate is referred to as being “on” another element, it may be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly stated to the contrary, the word “comprise” and variations such as “comprises” or “comprising” should be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

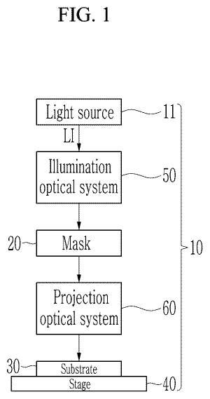

An exposure apparatus in an embodiment will now be described with reference to FIG. 1. FIG. 1 illustrates a schematic diagram showing an embodiment of an exposure apparatus.

The exposure apparatus 10 may be used in a photolithography process to form a pattern on a semiconductor device, a printed circuit board, and a liquid crystal substrate. The exposure apparatus 10 may form a fine pattern on a substrate 30 using a light LI including multiple wavelength ranges. The exposure apparatus 10 may be used in manufacturing a flat panel display, a liquid crystal display element, a semiconductor element, a micro-electro mechanical system (“MEMS”), etc.

The photolithography process may be a method for manufacturing a circuit pattern by printing a substrate using the light LI. The photolithography process may include a photoresist coating operation, an exposure operation, a develop operation, an etching operation, and a strip operation.

The exposure apparatus 10 may include a light source 11, an illumination optical system 50, a projection optical system 60, and a stage 40.

The light source 11 may emit the light LI for exposure. The light source 11 may emit the light LI having a predetermined wavelength range. The light source 11 may be a mercury lamp that emits ultraviolet rays. In an embodiment, the light source 11 may emit ultraviolet rays having a wavelength range of approximately 200 nanometers (nm) to 500 nm, for example. Additionally, the wavelength range of ultraviolet rays emitted by the light source 11 may be approximately 280 nm to 450 nm. The light LI emitted from the light source 11 may pass through the illumination optical system 50, a mask 20, and the projection optical system 60 in sequence to be irradiated onto a substrate 30 disposed on the stage 40.

The illumination optical system 50 may transfer the light LI emitted from the light source 11 to the mask 20. The illumination optical system 50 may correct the light LI emitted from the light source 11 to achieve uniform illumination. In addition, the illumination optical system 50 may efficiently focus the light LI emitted from the light source 11 to adjust it to a desired shape and angle. Performance of the illumination optical system 50 may have a significant impact on resolution and precision of the photolithography process.

The projection optical system 60 may transfer the light LI passing through the mask 20 onto the substrate 30. The projection optical system 60 may project a pattern on the mask 20 onto the substrate 30 in the photolithography process. The size of the pattern projected onto the substrate 30 may be reduced or enlarged compared to the size of the pattern formed on the mask 20. Additionally, the size of the pattern projected onto the substrate 30 may be the same as the size of the pattern formed on the mask 20. Performance of the projection optical system 60 may have a significant impact on resolution and precision of the photolithography process.

The stage 40 may precisely position and move the substrate 30. The stage 40 may precisely control the position of the substrate 30 such that a fine pattern may be accurately formed on the substrate 30.

The mask 20 may include a predetermined pattern that is projected and transferred onto the substrate 30. The mask 20 may include or consist of a transparent material, and may include an opaque light-blocking region that selectively blocks or passes optical wavelengths to form a pattern on a surface of the substrate 30.

The substrate 30 may serve as a foundation for manufacturing the semiconductor device. The substrate 30 may be a wafer or glass having a flat and even surface. A circuit pattern including or consisting of multiple layers may be formed on the substrate 30 by a photolithography process.

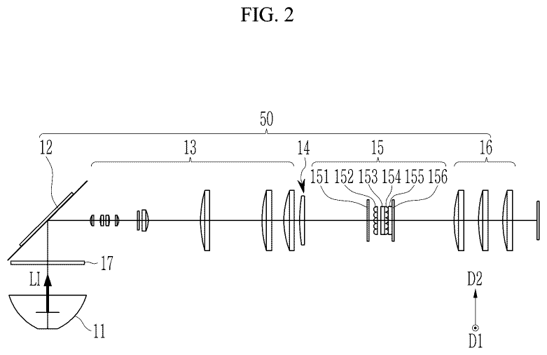

Hereinafter, the illumination optical system 50 of an embodiment will be specifically described with reference to FIG. 2. FIG. 2 illustrates an illumination optical system 50 with a light source 11 and a window 17. A description of components that are the same as the components described above will be omitted.

The window 17 may prevent damage to the illumination optical system 50. Additionally, the window 17 may prevent contamination of the illumination optical system 50. The window 17 may include transparent glass.

The illumination optical system 50 may include a mirror 12, a light range adjustment lens portion 13, an axicon lens 14, a fly-eye lens potion 15, and a condenser lens portion 16.

The mirror 12 may change a path of light by reflecting the light LI emitted from the light source 11. The mirror 12 may change the path of the light LI such that the light LI emitted from the light source 11 and passed through the window 17 is incident on the light range adjustment lens portion 13.

The light range adjustment lens portion 13 may receive the light LI emitted from the light source 11. The light range adjustment lens portion 13 may be disposed between the light source 11 and the axicon lens 14. The light range adjustment lens portion 13 may adjust an irradiation range of the light LI. The light LI passing through the light range adjustment lens portion 13 may be incident on the axicon lens 14.

The light range adjustment lens portion 13 may include multiple lenses. The lenses may have different or identical sizes. Additionally, the lenses may have different or identical refractive indices. In addition, the lenses may have different or identical curvature radii. The lenses included in the light range adjustment lens portion 13 may be selected and arranged as desired.

The axicon lens 14 may include a generatrix that is inclined at a constant angle from a center to an edge. The generatrix may be an inclined line extending from an apex of a cone to a base of the cone. Additionally, the generatrix may be an inclined line that connects two circular sections on a lateral surface of a truncated cone.

The axicon lens 14 may have an aspherical shape.

The axicon lens 14 may converge the light LI emitted from the light source 11. The light LI converged by the axicon lens 14 may be light emitted from the light source 11 and passed through the light range adjustment lens portion 13.

The fly-eye lens portion 15 may receive the light LI converged by the axicon lens 14.

The fly-eye lens portion 15 may include a first aperture 151, a first fly-eye lens 152, a second fly-eye lens 153, a third fly-eye lens 154, a fourth fly-eye lens 155, and a second aperture 156. The first aperture 151, the first fly-eye lens 152, the second fly-eye lens 153, the third fly-eye lens 154, the fourth fly-eye lens 155, and the second aperture 156 may be arranged in sequence along the path of light.

The first aperture 151 may directly receive the light LI from the axicon lens 14. The first aperture 151 may include a transmissive region that transmits the light LI and a non-transmissive region that does not transmit the light LI. The transmissive region may be formed in the center of the first aperture 151.

The first fly-eye lens 152, the second fly-eye lens 153, the third fly-eye lens 154, and the fourth fly-eye lens 155 included in the fly-eye lens portion 15 may be arranged sequentially. The first fly-eye lens 152 may be disposed apart from the first aperture 151. The second fly-eye lens 153 may be disposed apart from the first fly-eye lens 152, and may be next (adjacent) to the third fly-eye lens 154. The second fly-eye lens 153, the third fly-eye lens 154, and the fourth fly-eye lens 155 may be next (adjacent) to each other and stacked in a layered structure. The fourth fly-eye lens 155 may be next (adjacent) to the second aperture 156. A structure of the fly-eye lens portion 15 has been described with reference to FIG. 2, but the structure of the fly-eye lens portion 15 is not limited thereto. The fly-eye lens portion 15 may include a number of fly-eye lenses other than four, or may include one fly-eye lens.

The condenser lens portion 16 may receive the light LI emitted from the fly-eye lens portion 15, and may adjust illuminance of the emitted light LI to be uniform. Additionally, a size of an irradiation surface formed by the light LI may be adjusted. In an embodiment, an area size of the irradiation surface formed by the light LI passing through the condenser lens portion 16 may be 380×140 square millimeters (mm²), for example.

The condenser lens portion 16 may include a plurality of condenser lenses. The condenser lenses may have different or identical sizes. Additionally, the condenser lenses may have different or identical refractive indices. In addition, the condenser lenses may have different or identical curvature radii. The condenser lenses included in the condenser lens portion 16 may be selected and arranged as desired.

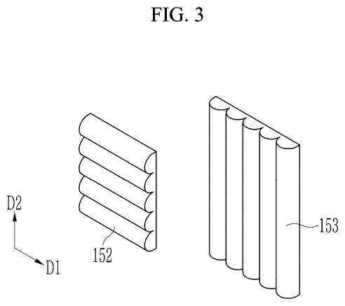

Hereinafter, the first fly-eye lens and the second fly-eye lens included in the fly-eye lens portion will be specifically described with reference to FIG. 3. FIG. 3 illustrates a perspective view showing a first fly-eye lens and a second fly-eye lens.

The first fly-eye lens 152 and the second fly-eye lens 153 may each include or consist of a plurality of cylinder lens arrays. A cylinder lens array may have an optical structure in which a plurality of cylinder lenses in a shape of cylinders or semi-circular cylinders are arranged. The cylinder lens array may be regularly arranged in a plan view. The cylinder lenses that make up the cylinder lens array may refract or focus light in a predetermined direction.

A direction in which the cylinder lens of the first fly-eye lens 152 extends and a direction in which the cylinder lens of the second fly-eye lens 153 extends may intersect each other. In an embodiment, the first fly-eye lens 152 may extend in a first direction D1, and the second fly-eye lens 153 may extend in a second direction D2 that is perpendicular to the first direction D1, for example.

The first fly-eye lens 152 including a cylindrical lens extending in the first direction D1 may focus light in the second direction D2 that is perpendicular to the first direction D1. The second fly-eye lens 153 including a cylinder lens extending in the second direction D2 may focus light in the first direction D1 that is perpendicular to the second direction D2.

The cylinder lens of the first fly-eye lens 152 may extend in a same direction as that of the cylinder lens of the third fly-eye lens. The first fly-eye lens 152 and the third fly-eye lens may focus light in a direction that is perpendicular to an extension direction of the cylinder lens. The first fly-eye lens 152 and the third fly-eye lens may be spaced apart from each other with their straight sections of a semicircular shape facing each other.

The cylinder lens of the second fly-eye lens 153 may extend in a same direction as that of the cylinder lens of the fourth fly-eye lens. The second fly-eye lens 153 and the fourth fly-eye lens may focus light in a direction that is perpendicular to an extension direction of the cylinder lens. The second fly-eye lens 153 and the fourth fly-eye lens may be spaced apart from each other with their straight sections of a semicircular shape facing each other.

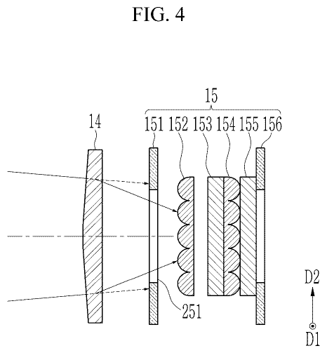

Hereinafter, a relationship between the axicon lens and the fly-eye lens portion will be specifically described with reference to FIG. 4. FIG. 4 illustrates light transferred from an axicon lens to a fly-eye lens portion.

The axicon lens 14 may include an inclined generatrix on a first surface. Additionally, the axicon lens 14 may include a second surface opposite to a first surface where the inclined generatrix is disposed. The second surface may be of a flat shape. Additionally, a groove may be defined in the second surface. The second surface of the axicon lens 14 may face the fly-eye lens portion 15. Additionally, the second surface of the axicon lens 14 may face the first aperture 151.

Light collected in the light range adjustment lens portion may pass through the axicon lens 14 and enter the fly-eye lens portion 15. Light collected in the light range adjustment lens portion may be incident on a first surface of the axicon lens 14, and may exit from the second surface of the axicon lens 14 toward the fly-eye lens portion 15.

The axicon lens 14 may include a straight generatrix on the first surface. Light incident on the axicon lens 14 may be refracted at the straight generatrix. Light refracted at the straight generatrix of the axicon lens 14 may not converge to a single point, but instead may exit the axicon lens 14 in a parallel manner. In other words, the axicon lens 14 may not be a spherical lens but rather a lens that includes a straight generatrix, so all light passing through the generatrix may be refracted at a same angle. Since light incident on the axicon lens 14 may be refracted at a same angle to exit the axicon lens 14, the axicon lens 14 may make the light propagate parallel while reducing a light irradiation range. Light that is refracted parallel to the axicon lens 14 and has a reduced light irradiation range may be incident on the fly-eye lens portion 15.

A smaller irradiation range of light incident on the fly-eye lens may be advantageous for forming high-resolution fine patterns on the substrate. The axicon lens 14 may adjust the irradiation range of light transmitted to the first aperture 151. The irradiation range of light passing through the first aperture 151 may be determined by a size of a transmissive region 251 of the first aperture 151. In an embodiment, when the irradiation range of light is circular, having a smaller radius centered on the circle allows the exposure apparatus to form high-resolution fine patterns on the substrate, for example. However, the axicon lens 14 may function to collect the light in a peripheral region of the irradiation range to the center. Accordingly, the axicon lens 14 may have an effect of substantially reducing the light irradiation range. Therefore, by aligning the axicon lens 14 next (adjacent) to the fly-eye lens portion 15 or the first aperture 151, the exposure apparatus may form a high-resolution fine pattern on the substrate.

Light collected from the axicon lens 14 may pass through the transmissive region of the first aperture 151. Light passing through the axicon lens 14 may be transferred to an inside of the fly-eye lens portion 15. The axicon lens 14 may refract light and transmit light blocked in the non-transmissive region of the first aperture 151 to the transmissive region 251. Accordingly, an amount of light passing through the transmissive region 251 of the first aperture 151 may increase, and illuminance of the light may be improved.

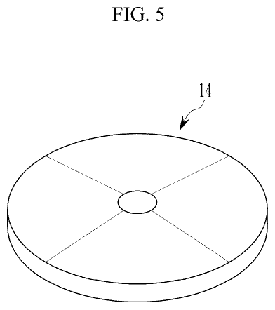

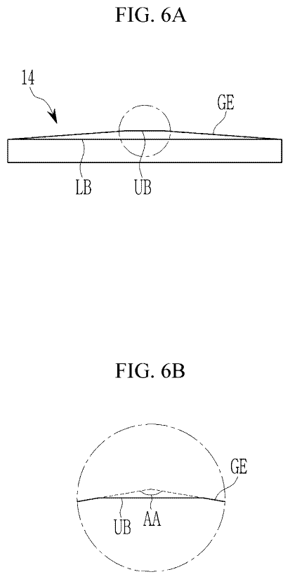

Hereinafter, a structure of an embodiment of an axicon lens will be described with reference to FIG. 5 and FIGS. 6A and 6B. FIG. 5 illustrates a perspective view showing an embodiment of an axicon lens, FIG. 6 illustrates a side view showing an embodiment of an axicon lens, and FIG. 6B is an enlarged view of a dot-dashed portion of FIG. 6B.

The axicon lens 14 may have a truncated cone shape with a first surface including a generatrix GE and a flat upper base UB, and a second surface opposite to the first surface may have a flat shape. This truncated cone shape may be a cone with a top portion cut off. That is, the truncated cone shape may be a shape obtained by cutting the top portion of the cone with a parallel cross-section.

The truncated cone shape formed on the first surface of the axicon lens 14 may include the upper base UB, a lower base LB, and the generatrix GE. The upper base UB may be a cross-section with the top portion of the cone cut off. The lower base LB may be a portion that faces the upper base UB of the truncated cone shape, and may have a larger area than that of the upper base UB. The generatrix GE may connect the upper base UB and the lower base LB. The generatrix GE may serve as a straight line forming a side surface of the truncated cone shape. When the axicon lens 14 is viewed from the side, a pair of generatrices GE may appear.

When the axicon lens 14 is viewed from the side, the pair of generatrices GE may form an apex angle AA. In a truncated cone, the apex angle AA may be an angle defined between the generatrices GE. In a truncated cone formed by cutting a top of a cone in a parallel manner to create the upper base UB, the apex angle AA may be an angle defined between the pair of generatrices GE of the truncated cone before the top of the cone was cut.

A diameter of the upper base UB disposed on the first surface of the axicon lens 14 may be approximately 40 mm to 60 mm. The diameter of the lower base LB disposed on the first surface of the axicon lens 14 may be approximately 300 mm to 500 mm. The apex angle AA of the truncated cone disposed on the first surface of the axicon lens 14 may be approximately 165° to 178°. As the apex angle AA increases, a refractive angle of the axicon lens 14 may increase, so the irradiation range of light transferred to the fly-eye lens portion may decrease.

In a case where the first surface of the axicon lens 14 has a truncated cone shape, the upper base UB disposed at the center of the axicon lens 14 is flat, so light passing through the upper base UB may be transferred to the fly-eye lens portion without distortion. This allows light to be focused at the center of an irradiation range of the light. Illumination and resolution of the exposure apparatus may be improved by focusing the light at the center of the light irradiation range.

The axicon lens 14 having a first surface with a truncated cone shape and a second surface with a flat shape may be referred to as a center flat axicon lens (“CFA lens”).

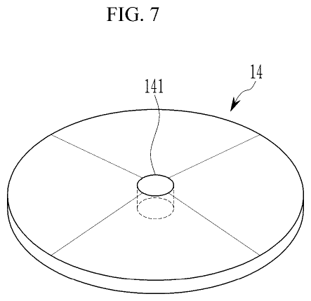

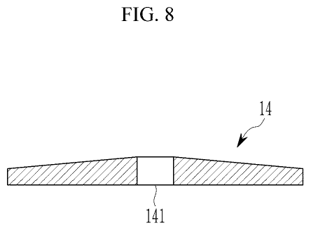

Hereinafter, a structure of another embodiment of an axicon lens will be described with reference to FIG. 7 and FIG. 8. FIG. 7 illustrates a perspective view showing another embodiment of an axicon lens, and FIG. 8 illustrates a cross-sectional view showing another embodiment of an axicon lens.

The axicon lens 14 may have a truncated cone shape with a first surface including the generatrix GE, and a second surface opposite to the first surface may have a flat shape. A through hole 141 may be defined in the center of the axicon lens 14 of FIGS. 7 and 8, unlike the axicon lens 14 of FIGS. 5 to 6B.

The through hole 141 defined at the center of the axicon lens 14 may extend from a first surface to a second surface of the axicon lens 14. When the through hole 141 is defined at the center of the axicon lens 14, light passing through the through hole 141 may be transferred to the fly-eye lens portion without distortion. This allows light to be focused at the center of an irradiation range of the light. Illumination and resolution of the exposure apparatus may be improved by focusing the light at the center of the light irradiation range.

A diameter of the through hole 141 may be approximately 40 mm to 60 mm. An angle of the axicon lens 14 may be approximately 165° to 178°.

The axicon lens 14 having a first surface with a truncated cone shape and a second surface with a flat shape and including the through hole 141 may be referred to as a center hole axicon lens (“CHA lens”).

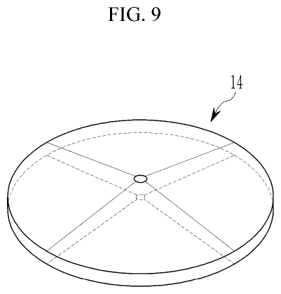

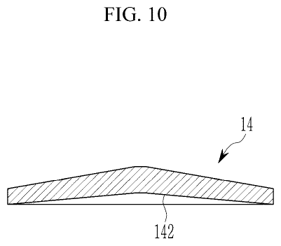

Hereinafter, another embodiment of an axicon lens will be described with reference to FIG. 9 and FIG. 10. FIG. 9 illustrates a perspective view showing another embodiment of an axicon lens, and FIG. 10 illustrates a cross-sectional view showing another embodiment of an axicon lens.

The axicon lens 14 may have a truncated cone shape with a first surface including the generatrix GE and the flat upper base UB, and a groove 142 may be defined in a second surface opposite to the first surface. The groove 142 on the second surface may have a truncated cone shape. The groove 142 on the second surface may be defined inside the axicon lens 14.

A truncated cone shape of the groove 142 in the second surface and a truncated cone shape on the first surface may be similar to each other. In addition, the truncated cone shape of the groove 142 in the second surface and the truncated cone shape on the first surface may not be similar to each other. In an embodiment, a generatrix of the truncated cone shape of the groove 142 on the second surface and a generatrix of the truncated cone shape on the first surface may have the same or different apex angles, for example.

The groove 142 may be defined in the second surface of the axicon lens 14, so the irradiation range of light emitted from the axicon lens 14 may be precisely adjusted. This is because the axicon lens 14 of FIG. 9 and FIG. 10 may refract light not only on the first surface but also on the second surface of the axicon lens 14.

The axicon lens 14 having the first surface with the truncated cone shape and the second surface defining the groove 142 with the truncated cone shape may be referred to as a dual-surface axicon lens (“DSA lens”).

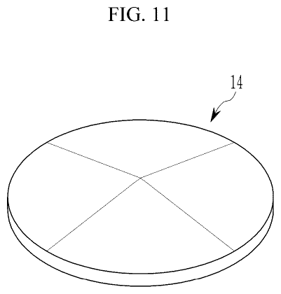

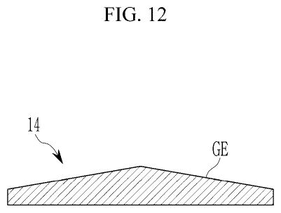

Hereinafter, a structure of another embodiment of an axicon lens will be described with reference to FIG. 11 and FIG. 12. FIG. 11 illustrates a perspective view showing another embodiment of an axicon lens, and FIG. 12 illustrates a cross-sectional view showing another embodiment of an axicon lens.

The first surface of the axicon lens 14 may have a conical shape. Additionally, the second surface of the axicon lens 14 may have a flat shape. A shape of a base of the conical shape of the first surface and a shape of the second surface may be the same.

In the conical shape, an angle at an apex of the cone may be approximately 165° to 178°.

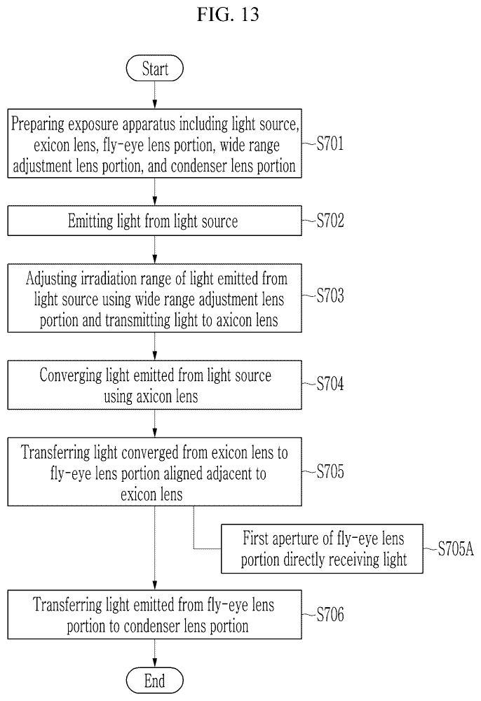

Hereinafter, an exposure method in an embodiment will be specifically described with reference to FIG. 13. FIG. 13 illustrates a flowchart of an embodiment of an exposure method according to the disclosure.

First, an operation (S701) of preparing an exposure apparatus including a light source, an axicon lens, a fly-eye lens portion, a light range adjustment lens portion, and a condenser lens portion may be performed. The fly-eye lens portion may include a plurality of fly-eye lenses. The light range adjustment lens portion may include a plurality of lenses. The condenser lens portion may include a plurality of condenser lenses.

Thereafter, an operation (S702) of emitting light from a light source may be performed. The light emitted from the light source may be ultraviolet rays. The light source may be a mercury lamp.

Next, an operation (S703) of adjusting an irradiation range of light emitted from the light source using the light range adjustment lens portion and transmitting the light to an axicon lens may be performed. The light may be adjusted to an appropriate irradiation range as it passes through the light range adjustment lens portion.

Thereafter, an operation (S704) of converging light emitted from the light source using the axicon lens may be performed. The light transferred to the axicon lens may be light that has passed through the light range adjustment lens portion. The axicon lens may have a generatrix on a first surface, and light may be refracted as it passes through the generatrix. The light passing through the axicon lens may have a narrow irradiation range.

Next, an operation (S705) of transferring light converged from the axicon lens to a fly-eye lens portion aligned next (adjacent) to the axicon lens may be performed. The axicon lens and a first aperture of the fly-eye lens portion may be aligned next (adjacent) to each other. The operation of transferring light converged from the axicon lens to the fly-eye lens portion aligned next (adjacent) to the axicon lens may include an operation (S705A) in which the first aperture of the fly-eye lens portion directly receives the light.

By aligning the axicon lens next (adjacent) to the fly-eye lens portion, light blocked in a non-transmissive region of the first aperture may be refracted into a transmissive region. Because the total amount of luminous flux transferred to the fly-eye lens increases, illuminance of the exposure apparatus may be increased. Additionally, resolution of a fine pattern formed on a substrate may be increased because more light is focused at the center of the light irradiation range.

Thereafter, an operation (S706) of transferring light emitted from the fly-eye lens portion to the condenser lens portion may be performed. The fly-eye lens portion may emit incident light. The condenser lens portion may receive light emitted from the fly-eye lens portion to adjust light intensity to be uniform.

By aligning the axicon lens and the fly-eye lens portion next (adjacent) to each other, the irradiation range of light transferred to the fly-eye lens portion may be reduced. The axicon lens may refract light to transmit light that is blocked by the first aperture of the fly-eye lens portion. This may improve illumination and resolution of the exposure apparatus.

While this disclosure has been described in connection with what is presently considered to be practical embodiments, it is to be understood that the disclosure is not limited to the disclosed embodiments, but, on the contrary, is intended to cover various modifications and equivalent dispositions included within the spirit and scope of the appended claims.

What is claimed is:

1. An exposure apparatus comprising:
a light source configured to emit light;
an axicon lens configured to converge the light emitted from the light source; and
a fly-eye lens portion configured to receive the light converged from the axicon lens,
wherein the axicon lens and the fly-eye lens portion are aligned next to each other.

2. The exposure apparatus of claim 1, further comprising
a light range adjustment lens portion disposed between the light source and the axicon lens and configured to adjust a light irradiation range of the light emitted from the light source.

3. The exposure apparatus of claim 1, further comprising
a condenser lens portion configured to receive light emitted from the fly-eye lens portion and configured to adjust illuminance of the emitted light to be uniform.

4. The exposure apparatus of claim 1, wherein
the fly-eye lens portion includes a first aperture including a transmissive region which transmits light, and
the first aperture directly receives light from the axicon lens, and the axicon lens and the first aperture are aligned next to each other.

5. The exposure apparatus of claim 1, wherein
a first surface of the axicon lens has a conical shape.

6. The exposure apparatus of claim 1, wherein
a first surface of the axicon lens has a truncated cone shape including a generatrix and a flat upper base.

7. The exposure apparatus of claim 6, wherein
a diameter of the flat upper base disposed on the first surface of the axicon lens is 40 millimeters to 60 millimeters.

8. The exposure apparatus of claim 6, wherein
a second surface of the axicon lens, which is opposite to the first surface, faces the fly-eye lens portion.

9. The exposure apparatus of claim 6, wherein
a groove having a truncated cone shape is define in a second surface of the axicon lens opposite to the first surface.

10. An illumination optical system comprising:
an axicon lens configured to converge light emitted from a light source; and
a fly-eye lens portion configured to receive the light converged from the axicon lens,
wherein the axicon lens and the fly-eye lens portion are aligned next to each other.

11. The illumination optical system of claim 10, further comprising
a condenser lens portion configured to receive light emitted from the fly-eye lens portion and configured to adjust illuminance of the emitted light to be uniform.

12. The illumination optical system of claim 10, wherein
the fly-eye lens portion includes a first aperture including a transmissive region which transmits light, and
the first aperture directly receives light from the axicon lens, and the axicon lens and the first aperture are aligned next to each other.

13. The illumination optical system of claim 10, wherein
a first surface of the axicon lens has a conical shape.

14. The illumination optical system of claim 10, wherein
a first surface of the axicon lens has a truncated cone shape including a generatrix and a flat upper base.

15. The illumination optical system of claim 14, wherein
a diameter of the flat upper base disposed on the first surface of the axicon lens is 40 millimeters to 60 millimeters.

16. The illumination optical system of claim 14, wherein
a second surface of the axicon lens, which is opposite to the first surface, faces the fly-eye lens portion.

17. The illumination optical system of claim 14, wherein
a groove having a truncated cone shape is defined in a second surface of the axicon lens opposite to the first surface.

18. An exposure method comprising:
preparing an exposure apparatus including a light source, an axicon lens, and a fly-eye lens portion;
emitting light from the light source;
converging the light emitted from the light source by the axicon lens; and
transferring the light converged from the axicon lens to the fly-eye lens portion aligned next to the axicon lens.

19. The exposure method of claim 18, wherein
the fly-eye lens portion includes a first aperture which includes a transmissive region and is aligned next to the axicon lens, and
the transferring of the light converged from the axicon lens to the fly-eye lens portion aligned next to the axicon lens includes
the first aperture of the fly-eye lens portion directly receiving the light.

20. The exposure method of claim 18, wherein
a first surface of the axicon lens has a truncated cone shape including a generatrix and an upper base, and
a second surface of the axicon lens, which is opposite to the first surface, faces the fly-eye lens portion.
